(19) United States
(12) Patent Application Publication
(10) Pub. No.: US 2009/0026388 A1
(43) Pub. Date: Jan. 29, 2009

(54) Illumination Homogenizer

(76) Inventor: Zbigniew M. Drozdowicz, Orange, CT (US)

Correspondence Address: ST. ONGE STEWARD JOHNSTON & REENS, LLC, 986 BEDFORD STREET, STAMFORD, CT, 06905-5619, US

(21) Appl. No.: 11/782,937

(22) Filed: Jul. 25, 2007

(51) Int. Cl. H01L 21/00; G02B 3/00

(52) U.S. Cl. 250/492.2; 359/741

(57) ABSTRACT

An illumination homogenizer is provided, including a fly eye-type lens array for receiving radiation from a source, the lens array being comprised of a twelve-lenslet subset of a 4×4 array of lenslets. The illumination homogenizer including a lens array comprised of a 4×4 array of lenslets, or a subset thereof, is also used in combination with a negative lens between a radiation source and the lens array.

### FIELD OF THE INVENTION

The present invention relates to an illumination system for providing uniform illumination and high optical transfer efficiency from a lamp source to a work plane. In particular, the present invention relates to an illumination homogenizer.

### BACKGROUND OF THE INVENTION

Illumination systems that provide substantially uniform illumination are well known and have various uses in industry. For example, illumination systems that provide uniform illumination play a critical role in the process of optical lithography. Optical lithography is used in the manufacture of semiconductors and liquid crystal display elements. In optical lithography, light is used to transfer a pattern onto a substrate surface such as a wafer or glass plate. First, a ‘photoresist’ (a light-sensitive chemical) is applied to the substrate on which the pattern is to be applied. Then, the substrate is exposed to the desired spectrum and intensity of light through a photomask which contains the desired pattern. The photoresist undergoes a chemical change due to the incident light which either weakens or strengthens (depending on the photoresist) the portions of the substrate which were exposed to the light. The substrate is further developed and then chemically etched so that the uppermost layer of the substrate is removed in the regions that were either weakened or not strengthened by the light exposure. During the exposure step, it is important that the light incident on the substrate be as uniform as possible so that the unwanted regions of the substrate will be capable of easy removal.

Contact printing and proximity printing are two techniques used in optical lithography. In contact printing, the photomask is pressed against the wafer during the exposure step, wherein the light used has a wavelength in the ultraviolet range. In proximity printing, the photomask is not brought into contact with the wafer, but instead is held around 20-50 microns away from the wafer.

Uniform illumination is also important in photomechanical processing and other applications wherein an image is to be projected onto a larger screen. Photomechanical processing includes the projection of the image of an original onto a presensitized plate through a projection optical system. As a further example, illumination homogenizers are employed in commercial ‘solar simulators.’ Solar simulators are used to create illumination which matches, as closely as possible, the spectrum of radiation from the sun as well as the uniform intensity of radiation from the sun.

Illumination systems which are used in the foregoing processes and devices must employ an illumination homogenizer. An illumination homogenizer modifies a beam of radiation from a source which has non-uniform intensity so as to improve the uniformity or homogeneity of the beam of radiation. Many illumination homogenizers employ one or more lens arrays, or ‘fly eye’ lens arrays, to modify the beam of radiation. Each lens array generally comprises a group of small ‘lenslets’ held together by a frame. A lenslet is a small lens which is shaped so that it fits together with other lenslets to form the array.

The manner in which lens arrays homogenize radiation is well-known in the art. Briefly, radiation from a source often has an intensity that is not uniform over the entire beam, whether as a result of the nature of the source or due to a reflection from, for example, an elliptical reflector which condenses the radiation. The first lens array takes the single non-uniform beam and divides it into a number of beams equal to the number of lenslets in the array. Each smaller beam has a smaller degree of non-uniformity than the initial, single non-uniform beam. The second lens array transmits the smaller beams toward a lens and superimposes the smaller beams on each other and onto a work plane.

There are various examples in the prior art of systems and devices intended to provide uniformity or homogeneity of light in illumination systems. For example, U.S. Pat. No. 4,884,869 to Uemura describes fly eye lens arrays for use in an illumination system. Each lens array disclosed therein comprises 25 lenslets held within a frame. The fly eye lens array is placed at the converging point of an ellipsoidal mirror in the illumination system. Other homogenizers which implement fly eye lens arrays are described in U.S. Pat. No. 6,318,863 to Tiao et al., U.S. Pat. No. 5,594,587 to Komatsuda et al., and U.S. Pat. No. 5,418,583 to Masumoto. However, the homogenizer devices disclosed in these systems suffer from significant drawbacks.

First, most homogenizer devices of the lens array type utilize a relatively large number of lenslets. It is customary to use a minimum of 25 lenslets and sometimes more than 80 lenslets in a single lens array. Traditionally, a large number of lenslets have been preferred in order to obtain effective homogenization. Unfortunately, a large number of lenslets means a large number of lens-edge to lens-edge contact areas, i.e. the areas in which lenslets abut each other.

It has been found that the efficiency of the illumination system is decreased as a result of the large number of edge-to-edge contact of the lenslets in the lens arrays. As shown for example in FIG. 2, which shows a close-up view of two lens arrays of an illumination homogenizer, light that passes from one lenslet to another lenslet within the same lens array through the side edges of the lenslets is usually then not directed toward a ‘downstream’ collimating lens. (The terms ‘downstream’ and ‘upstream’ as used herein refer to positions along the optical path, such that the radiation source is the furthest point upstream and the work plane is the furthest point downstream.) Such light ‘leaks’ out of the system and does not reach the work plane. The light which is leaked is indicated by the rays labeled with reference number 20. As the number of lenslets in the arrays is increased, the amount of light leaked is also increased. This light leakage significantly reduces the efficiency of the illumination system.

A second drawback is that the use of a relatively large number of lenslets significantly increases the cost and complexity of illumination homogenizers. Lenslets are precisions components which are expensive to produce. Larger lens arrays are more difficult and time-consuming to construct because of the greater number parts (lenslets). Cleaning and maintaining a lens array with a large number of lenslets is also more time-consuming. Therefore, in addition to the larger cost associated with making or purchasing a greater number of lenses, the cost of labor associated with the larger lens arrays is also larger.

What is needed, therefore, is an illumination homogenizer with a lens array design that maximizes the efficiency of the illumination system while still effectively homogenizing non-uniform radiation and that is inexpensive to manufacture and maintain.

### SUMMARY OF THE INVENTION

It is an object of the present invention to provide an illumination homogenizer which maximizes the efficiency of an illumination system.

It is a further object of the present invention to provide an illumination homogenizer which effectively homogenizes radiation from a source which is of non-uniform intensity.

It is another object of the present invention to provide an illumination homogenizer which is inexpensive to produce and maintain.

These and other objects are accomplished by a first embodiment of the present invention by provision of an illumination homogenizer comprising a lens array for receiving radiation from a source, wherein the lens array is composed of twelve lenslets. In some embodiments, the lens array is a first lens array, and the illumination homogenizer further comprises a second lens array for receiving radiation from the first lens array. In some embodiments, the second lens array is comprised of no more than sixteen lenslets. In some embodiments, the illumination homogenizer further comprises a source of radiation. In some embodiments, the illumination homogenizer is adapted for use in contact printing. In some embodiments, the illumination homogenizer is adapted for use in proximity printing. In some embodiments, the illumination homogenizer further comprises a negative lens disposed between the source of radiation and the lens array. In some embodiments, the lens array is cross-shaped.

According to a second embodiment of the present invention, an illumination homogenizer is provided, comprising a negative lens for receiving radiation from a source, and a lens array for receiving radiation from the negative lens. In some embodiments, the lens array is comprised of no more than sixteen lenslets. In some embodiments, the lens array is composed of twelve lenslets. In some embodiments, the lens array is cross-shaped. In some embodiments, the lens array is a first lens array, and the illumination homogenizer further comprises a second lens array for receiving radiation from the source. In some embodiments, the second lens array is comprised of no more than sixteen lenslets. In some embodiments, the illumination homogenizer is adapted for use in contact printing. In some embodiments, the illumination homogenizer is adapted for use in proximity printing.

According to a third embodiment of the present invention, an illumination system is provided, comprising a source of radiation having a spectral distribution corresponding to radiation from the sun and an illumination homogenizer for receiving radiation from the source, wherein the illumination homogenizer comprises a lens array comprised of no more than sixteen lenslets for receiving radiation from the source.

In some embodiments, the lens array is comprised of sixteen lenslets. In some embodiments, the lens array is composed of twelve lenslets. In some embodiments, the lens array is cross-shaped. In some embodiments, the illumination system further comprises a negative lens disposed between the source of radiation and the lens array. In some embodiments, the lens array is a first lens array, and the illumination homogenizer further comprises a second lens array comprised of no more than sixteen lenslets for receiving radiation from the source. In some embodiments, the illumination system further comprises an optical element for directing radiation from the source to the illumination homogenizer. In some embodiments, the optical element is an elliptical reflector. In some embodiments, the illumination system further comprises a positive lens for receiving radiation from the illumination homogenizer.

Other objects of the invention and its particular features and advantages will become more apparent from consideration of the following drawings and accompanying detailed description.

### BRIEF DESCRIPTION OF THE DRAWINGS

FIG. 1 is a schematic diagram of an illumination system as known in the prior art.

FIG. 2 is a schematic diagram of an illumination homogenizer including two lens arrays.

FIG. 3 is a schematic diagram of an illumination system including an illumination homogenizer according to one embodiment of the present invention.

FIG. 4 is a plan view of a lens array used in the illumination homogenizer of FIG. 3.

FIG. 4A is a plan view of a lens array used in the illumination homogenizer of FIG. 3.

FIG. 5 is a perspective view of three lenslets used in a lens array of the illumination homogenizer shown in FIG. 3

FIG. 6 is a schematic diagram of an illumination homogenizer in combination with a negative lens according to one embodiment of the present invention.

### DETAILED DESCRIPTION OF THE DRAWINGS

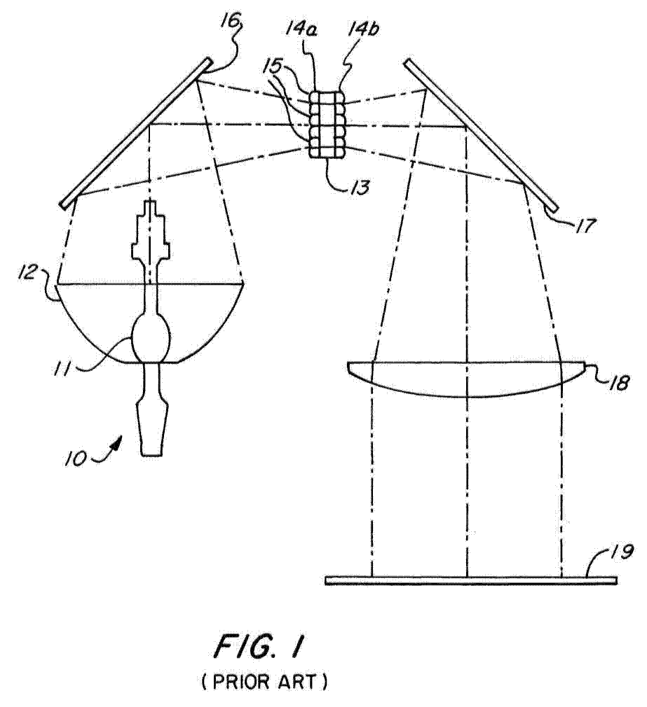

Embodiments of the present invention will now be described with reference to the drawings, wherein like reference numerals designate corresponding structure throughout the views. A typical illumination system 10 according to the prior art, which includes an illumination homogenizer, is shown in FIG. 1. A lamp source 11 is positioned near one of the foci of an elliptical reflector 12. The light from lamp source 11 is directed from the elliptical reflector 12 by a reflector 16 to the illumination homogenizer 13, which consists of two ‘fly eye’ lens arrays 14a and 14b. In the system 10 shown in FIG. 1, each fly eye lens array 14 includes six columns and six rows of lenslets 15 for a total of 36 lenslets per lens array 14. After passing through the lens arrays 14a and 14b, the light is then directed by a second reflector 17 to a collimating lens 18 which projects the light outward and to a work plane 19. Many illumination systems also include filters and other components used to spectrally shape the radiation output of the system. For example, the reflectors 16 and 17 can be designed to perform a spectral stripping dichroic function. The use of such components is described in more detail below.

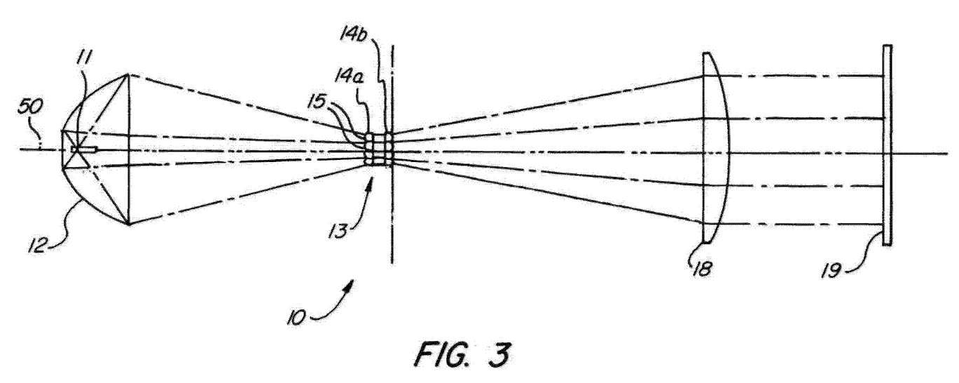

FIG. 3 shows a schematic view of an illumination system 10 which includes an illumination homogenizer 13 according to one exemplary embodiment of the present invention. The illumination system comprises a radiation source 11 positioned at or near a focal point of an elliptical reflector 12, an illumination homogenizer 13, and a collimating lens 18.

The radiation source 11 produces electromagnetic radiation, the spectrum of which is selected based upon the intended application of the system. In some embodiments, the radiation source 11 has a cylindrical shape and is disposed on the main optical axis 50 of the illumination system. In other embodiments, the radiation source 11 has a spherical or more rounded shape. In any event, however, the radiation source 11 is a volume light source and not the hypothetical and ideal point source of radiation. Use of such a volume light source in combination with an elliptical or parabolic reflector causes the non-uniform illumination which is the problem to be addressed by illumination homogenizers.

The elliptical reflector 12 collects and condenses the radiation emitted from the source 11 and directs it to the illumination homogenizer 13. Due to its shape, the elliptical reflector 12 produces a beam of radiation which is not of uniform intensity such that the emerging beam has regions of higher intensity and other regions of lower intensity. In general, the irradiance profile of the beam emerging from the elliptical reflector is a Gaussian-type, wherein the central regions of the beam have higher intensity than the outer regions. Often such an irradiance profile is a modified Gaussian-type, having a region of low intensity directly in the center of the beam.

The illumination homogenizer 13 shown in FIG. 3 is disposed ‘downstream’ of the source 11 and the elliptical reflector 12 and is used to ‘flatten’ the irradiance profile of the beam emerging from the reflector 12 into a beam having an irradiance profile that is more uniform. In the embodiment shown in FIG. 3, the homogenizer 13 is comprised of two lens arrays 14a and 14b, which are disposed in series along the optical path. In the embodiment shown in FIG. 3, each lens array 14 is comprised of twelve lenslets.

The first lens array 14a of the illumination homogenizer 13, sometimes referred to as the objective array, divides the non-uniform beam into a number of beams corresponding to the number of lenslets in the first lens array, in the case of the homogenizer 13 shown in FIG. 3, twelve. These twelve beams are more uniform than the primary beam. The second lens array 14b of the illumination homogenizer 13, sometimes referred to as the field array, is usually disposed at or near the image plane of the first lens array 14a. The second lens array 14b superimposes the twelve beams onto each other and onto the work plane 19. A positive lens 18, as shown in FIG. 3, acts to collimate the radiation which emerges from the illumination homogenizer 13. The collimated radiation is then incident on work plane 19, and the radiation has improved intensity uniformity.

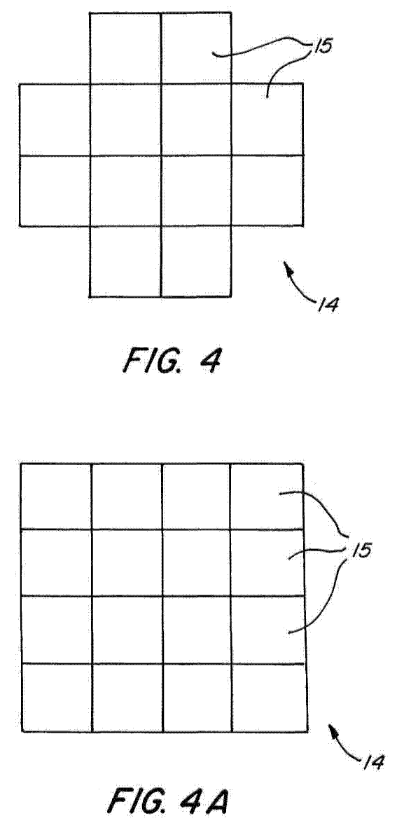

FIGS. 4 and 4A show plan views of lens arrays 14 which are employed in illumination homogenizers according to the present invention. FIG. 4 shows a lens array 14 having twelve lenslets 15. This array is a subset of a 4×4 lens array. In this advantageous embodiment of the present invention, the lens array 14 is cross-shaped. The cross-shaped lens array 14 shown in FIG. 4 provides excellent optical efficiency while minimizing the cost and complexity of the system by using a small number of lenslets. FIG. 4A shows a full 4×4 lens array 14 comprising sixteen lenslets 15. This embodiment also provides excellent optical efficiency coupled with low cost and complexity. Both the sixteen-lenslet array and the twelve-lenslet array provide a relatively small number of lens-edge to lens-edge contact areas so as to minimize leakage by reducing the number of rays which cross between the side walls of the lenslets, while still producing effective illumination homogenization. The twelve-lenslet array provides high efficiency at a slightly lower cost than the sixteen-lenslet array, while the sixteen-lenslet array provides slightly better illumination homogenization.

It has been found that, while a 3×3 lens array will provide a further increase in the efficiency of the system by further reducing the number of lens-edge contact areas, arrays smaller than a 4×4 array or 4×4 subset do not provide sufficient homogenization of the illumination.

The efficiency of the illumination system 10 is improved by the illumination homogenizers according to the present invention because more of the radiation produced by the radiation source 11 is transmitted to the work plane 19. By significantly cutting down on leakage, the system 10 may be operated with a lower power radiation source while still obtaining a satisfactory level of illumination of the work plane 19.

While the figures show homogenizers according to the present invention which include two lens arrays 14 having the same configuration and number of lenslets, some embodiments include lens arrays having distinct configurations and numbers of lenslets. For example, in one embodiment, one lens array is the twelve-lenslet, cross-shaped subset of the 4×4 array while the other is the full sixteen-lenslet, 4×4 array. These design choices are determined by the intended use of the illumination homogenizer and illumination system.

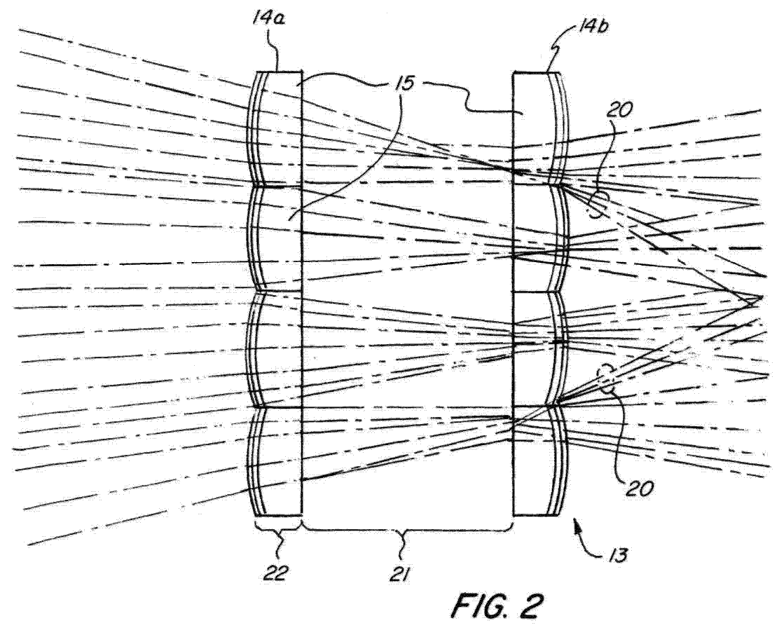

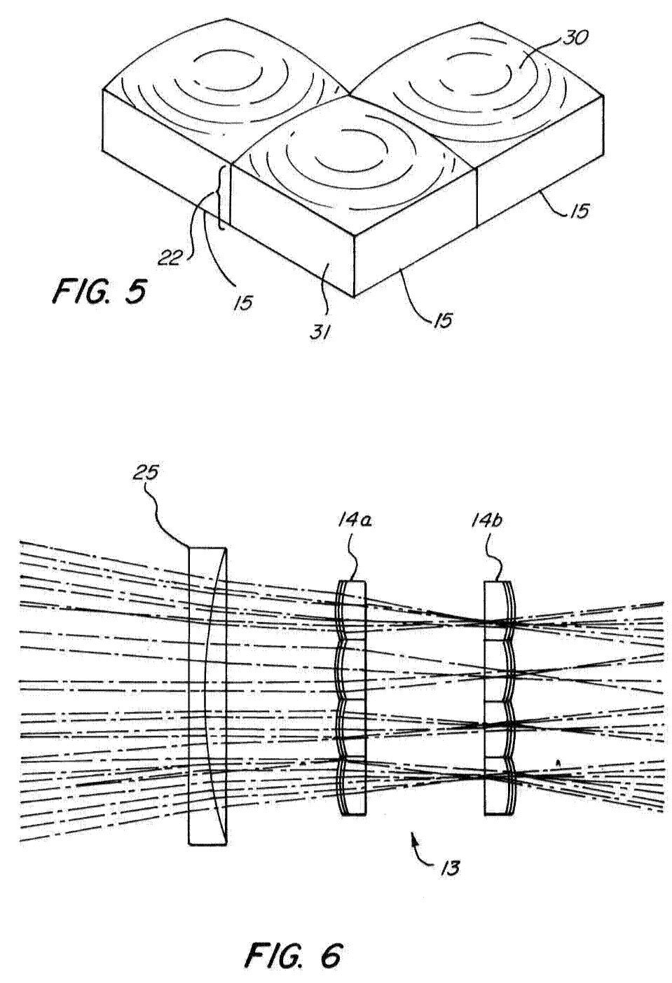

Referring now to FIG. 5, a perspective view of three lenslets 15 for use in illumination homogenizers according to the present invention shows the shape and design of the lenslets 15. The lenslets 15 have a square profile, or aperture, so that they fit together in the array without gaps. In some embodiments, lenslets with a rectangular but non-square shape are used and in other embodiments, a combination of square and rectangular lenslets are used in a single lens array. The lenslets 15 have a convex, curved surface 30 and a planar surface 31. In effect, a lenslet is a rectangular section of a lens. The curved surface 30 is spherical in the embodiment shown in FIG. 5, however, anamorphic surfaces are used in some embodiments. The lenslets 15 have a thickness 22. While the lenslets 15 shown in FIGS. 2 and 5 have one curved surface and one planar surface, in other embodiments, both surfaces are curved.

Referring again to FIG. 2, the lens arrays 14a and 14b are separated by a distance 21 and the lenslets 15 have a thickness 22. The distance 21 and thickness 22, along with the size and material make-up of the lenslets, are varied according to the intended application of the illumination homogenizer 13 and the illumination system as a whole. In general, the distance 21 is selected so that the second lens array 14b is located at the image plane of the first lens array 14a. In some embodiments, the distance 21 between the lens arrays 14 is variable and may be adjusted according to the particular application so that the system may be used with various radiation sources which emit radiation of various wavelengths.

FIG. 6 shows another embodiment of the present invention. The illumination homogenizer 13 shown in FIG. 6 is part of an illumination system such as those shown in FIGS. 1 and 3. The homogenizer 13 is again comprised of two lens arrays 14a and 14b, each lens array being a 4×4 array of lenslets, a twelve-lenslet subset of a 4×4 array, or combinations thereof. The embodiment shown in FIG. 6, however, also includes a negative lens 25 positioned ‘upstream’ of the lens arrays 14a and 14b. The negative lens 25 is positioned between the source of radiation and the first lens array 14a.

The purpose of the negative lens 25 is to reduce the angular content and the angle of incidence of radiation incident on the lens arrays 14. Use of a negative lens 25 according to the present invention brings at least two substantial benefits. First, the rays which enter the lens arrays 14 after passing through the negative lens 25 enter with a smaller angle of incidence. This further reduces the amount of radiation which crosses between lenslets through their side surfaces and hence further reduces the amount of light leakage.

Second, the negative lens 25 reduces the angular content of the beam of radiation. This allows for better utilization of angle tunable spectral shaping components. Both absorbing and thin interference film-based spectral shaping components have spectral behaviors that are angular dependent. When the light incident on such components has a lower angular content, the spectral behavior of the shaping components is easier to model and adjust. For example, a Schott WG320 glass filter is used to control the ultraviolet content of the radiation of a solar simulator. The tilt angle of the filter will modify the absorbing thickness of the filter. Such angular dependence is most easily predicted and adjusted when the angular content of the incident beam is not excessive.

The negative lens 25 is incorporated into the illumination system 10 in a variety of ways, depending on the particular embodiment. In some embodiments, the negative lens 25 is an independent component which may be installed and removed without affecting the other components of the system. In other embodiments, the negative lens 25 is a part of the illumination homogenizer 13, such that the negative lens 25 and the other components of the homogenizer 13 (e.g. a first lens array and a second lens array) are coupled together as a unit.

As stated above, the type of radiation source 11 determines the particular application of the illumination system. In one embodiment intended for use in optical lithography, radiation from the ultraviolet portion of the electromagnetic spectrum is typically used. Radiation sources typically used in optical lithography include Mercury arc lamps and Mercury-Xenon arc lamps, which provide ultraviolet and deep ultraviolet radiation. Embodiments of the present invention are employed in optical lithography applications to provide uniform illumination, such applications including contact printing and proximity printing techniques.

In another advantageous embodiment, the radiation source 11 produces radiation which matches the radiation produced by the sun. One such radiation source is a short arc Xenon lamp, which is capable of closely mimicking natural daylight. In such an embodiment, the illumination system 10 is referred to as a ‘solar simulator.’ As stated above, solar simulators are used to create illumination which matches, as closely as possible, the spectrum of radiation from the sun as well as the uniform intensity of radiation from the sun.

Thus, illumination homogenizers which employ features of the present invention provide improved efficiency for illumination systems which generate uniform illumination. Illumination homogenizers according to the present invention are also inexpensive to manufacture and maintain. Embodiments of the present invention improve such processes as photomechanical processing and the use of optical lithography in the manufacture of semiconductors and liquid crystal displays. Embodiments of the present invention also improve such devices as solar simulators and large-screen projectors. Illumination homogenizers according to the present invention may be employed in nearly any illumination system from which uniform illumination is desired.

Although the invention has been described with reference to a particular arrangement of parts, features and the like, these are not intended to exhaust all possible arrangements or features, and indeed many modifications and variations will be ascertainable to those of skill in the art.

What is claimed is:

1. An illumination homogenizer, comprising a lens array for receiving radiation from a source, wherein the lens array is composed of twelve lenslets.

2. The illumination homogenizer of claim 1, wherein the lens array is a first lens array, and further comprising a second lens array for receiving radiation from the first lens array.

3. The illumination homogenizer of claim 2, wherein the second lens array is comprised of no more than sixteen lenslets.

4. The illumination homogenizer of claim 1, further comprising a source of radiation.

5. The illumination homogenizer of claim 4, wherein the illumination homogenizer is adapted for use in contact printing.

6. The illumination homogenizer of claim 4, wherein the illumination homogenizer is adapted for use in proximity printing.

7. The illumination homogenizer of claim 4, further comprising a negative lens disposed between the source of radiation and the lens array.

8. The illumination homogenizer of claim 1, wherein the lens array is cross-shaped.

9. An illumination homogenizer, comprising a negative lens for receiving radiation from a source, and a lens array for receiving radiation from the negative lens.

10. The illumination homogenizer of claim 9, wherein the lens array is comprised of no more than sixteen lenslets.

11. The illumination homogenizer of claim 9, wherein the lens array is composed of twelve lenslets.

12. The illumination homogenizer of claim 11, wherein the lens array is cross-shaped.

13. The illumination homogenizer of claim 9, wherein the lens array is a first lens array, and further comprising a second lens array for receiving radiation from the first lens array.

14. The illumination homogenizer of claim 13, wherein the second lens array is comprised of no more than sixteen lenslets.

15. The illumination homogenizer of claim 9, wherein the illumination homogenizer is adapted for use in contact printing.

16. The illumination homogenizer of claim 9, wherein the illumination homogenizer is adapted for use in proximity printing.

17. An illumination system, comprised of:
a source of radiation having a spectral distribution corresponding to radiation from the sun; and
an illumination homogenizer for receiving radiation from the source;
wherein the illumination homogenizer comprises a lens array comprised of no more than sixteen lenslets for receiving radiation from the source.

18. The illumination system of claim 17, wherein the lens array is composed of sixteen lenslets.

19. The illumination system of claim 17, wherein the lens array is composed of twelve lenslets.

20. The illumination system of claim 19, wherein the lens array is cross-shaped.

21. The illumination system of claim 17, further comprising a negative lens disposed between the source of radiation and the lens array.

22. The illumination system of claim 17, wherein the lens array is a first lens array and wherein the illumination homogenizer further comprises a second lens array comprised of no more than sixteen lenslets for receiving radiation from the first lens array.

23. The illumination system of claim 17, further comprising an optical element for directing radiation from the source to the illumination homogenizer.

24. The illumination system of claim 23, wherein the optical element is an elliptical reflector.

25. The illumination system of claim 17, further comprising a positive lens for receiving radiation from the illumination homogenizer.
